(19) United States
(12) Patent Application Publication
(10) Pub. No.: US 2013/0264640 A1
(43) Pub. Date: Oct. 10, 2013

(54) DRAIN EXTENDED MOS TRANSISTOR HAVING SELECTIVELY SILICIDED DRAIN

(71) Applicants: AKRAM A. SALMAN, PLANO, TX (US); FARZAN FARBIZ, DALLAS, TX (US); ARAVIND C. APPASWAMY, DALLAS, TX (US); JOHN ERIC KUNZ, JR., ALLEN, TX (US); GIANLUCA BOSELLI, PLANO, TX (US)

(72) Inventors: AKRAM A. SALMAN, PLANO, TX (US); FARZAN FARBIZ, DALLAS, TX (US); ARAVIND C. APPASWAMY, DALLAS, TX (US); JOHN ERIC KUNZ, JR., ALLEN, TX (US); GIANLUCA BOSELLI, PLANO, TX (US)

(73) Assignee: TEXAS INSTRUMENTS INCORPORATED, Dallas, TX (US)

(21) Appl. No.: 13/441,318

(22) Filed: Apr. 6, 2012

(51) Int. Cl. H01L 29/78; H01L 21/336

(52) U.S. Cl. 257/343; 438/197; 257/E29.261; 257/E21.409

(57) ABSTRACT

A method of forming a drain extended metal-oxide-semiconductor (MOS) transistor includes forming a gate structure including a gate electrode on a gate dielectric on a semiconductor surface portion of a substrate. The semiconductor surface portion has a first doping type. A source is formed on one side of the gate structure having a second doping type. A drain is formed including a highly doped portion on another side of the gate structure having the second doping type. A masking layer is formed on a first portion of a surface area of the highly doped drain portion. A second portion of the surface area of the highly doped drain portion does not have the masking layer. Selectively siliciding is used to form silicide on the second portion. The masking layer blocks siliciding on the first portion so that the first portion is silicide-free.

### FIELD

Disclosed embodiments relate to drain extended metal-oxide-semiconductor (MOS) transistors.

### BACKGROUND

Some electronic devices require transistors to operate at drain-source voltages substantially higher than that of logic transistors or memory transistors. Such transistor devices are referred to as high voltage transistors that can be employed for power related tasks, such as power source switching.

Conventional high voltage transistors comprise drain extended MOS transistors, including what is generally referred to as drain extended MOS (DEMOS) and related drain extended structures including lateral diffused MOS (LDMOS). Such conventional drain extended MOS transistors all generally have poor electrostatic discharge (ESD) performance, irrespective of their voltage rating. The main reason for poor ESD performance of such transistors is believed to be current filamentation after snapback, where the filament formed is not able to the carry the transient current induced by the ESD event, and as a result the drain extended MOS transistor fails destructively.

Known approaches that attempt to solve this problem include self-protecting drivers in MOS conduction mode by use of very large geometries, typically >4,000 μm (4 mm) in dimension. However, this approach results in a large capacitance/leakage/footprint. Another approach embeds a silicon-controlled rectifier (SCR) into the drain extended MOS transistor (MOS-SCR), where the SCR acts as a shunt. However, this approach is only for SCR-tolerant applications where a low holding voltage after snapback can be accepted on the pins, which tend to be few applications. Yet another approach involves the engineering of an ad-hoc component (i.e. bipolar transistor) to protect an ESD vulnerable conventional drain extended MOS transistor. However, adding the ad-hoc component can be expensive due to the need for new component development, and may not meet high voltage (HV) operating requirement, such as a >20V drain-source breakdown voltage for typical high voltage transistor applications (e.g., automotive applications).

### SUMMARY

Disclosed embodiments recognize although conventionally siliciding over the full area of the highly doped (e.g., N+ or P+) drain portion for drain extended metal-oxide-semiconductor (MOS) transistors minimizes series resistance which improves operating performance (e.g., Rdson), conventional full area siliciding of the highly doped drain portion can degrade the ESD performance. As described herein, partial siliciding of the highly doped drain portion of drain extended MOS transistors, such as DEMOS and LDMOS transistors, has been found to improve the ESD performance to approach the ESD performance of intrinsic (no silicide on the highly doped drain) drain extended MOS transistors, with only a minimal increase in Rdson and thus minimal loss of current handling capability as compared to conventional drain extended MOS transistors having silicide over the full area of the highly doped drain. As a result, disclosed drain extended MOS transistors having partially silicided highly doped drain portions can provide self-protection from ESD events, with operating performance comparable to conventional drain extended MOS transistors, such as conventional DEMOS or LDMOS transistors that have silicide over the full area of their highly doped drain.

One embodiment comprises a method of forming a drain extended MOS transistor which includes forming a gate structure including a gate electrode on a gate dielectric on a semiconductor surface portion of a substrate. The semiconductor surface portion has a first doping type. A source is formed on one side of the gate structure having a second doping type. A drain including a highly doped drain is formed on another side of the gate structure having the second doping type. As used herein, a “highly doped drain portion” refers to a drain portion having a minimum n-type or p-type dopant concentration sufficient to provide ohmic contact to a metal. Typically, a surface doping concentration of ≧5×10¹⁹ cm⁻³ is needed to provide an ohmic contact to an n-type drain.

A masking layer is formed on a first portion of a surface area of the highly doped drain portion. A second portion of the surface area of the highly doped drain portion does not have the masking layer. Selectively siliciding is used to form silicide on the second portion. The masking layer blocks siliciding on the first portion so that the first portion is silicide-free. Integrated circuits (IC) including at least one disclosed drain extended MOS transistor having a partially silicided N+ or P+ drain are also described herein.

### BRIEF DESCRIPTION OF THE DRAWINGS

Reference will now be made to the accompanying drawings, which are not necessarily drawn to scale, wherein:

FIG. 1 is a flow chart that shows steps in an example method for forming a drain extended MOS transistor having a partially silicided highly doped drain portion, according to an example embodiment.

FIG. 2A is a cross-sectional depiction of an example drain extended n-channel MOS (DENMOS) transistor having a partially silicided N+ drain, according to an example embodiment.

FIG. 2B is a cross-sectional depiction of an example lateral diffused n-channel MOS (LDNMOS) transistor having a partially silicided N+ drain, according to an example embodiment

FIGS. 3A-D shows top views of several example DENMOS transistors having silicide-free N+ drain configurations including C-shaped, rectangular, ring interdigitated, and circular/racetrack shaped, respectively, according to example embodiments.

FIG. 4 shows the ESD performance improvement for disclosed DENMOS transistors for N+ drains having various silicide blocking lengths vs. a control DENMOS transistor having a fully silicided N+ drain, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

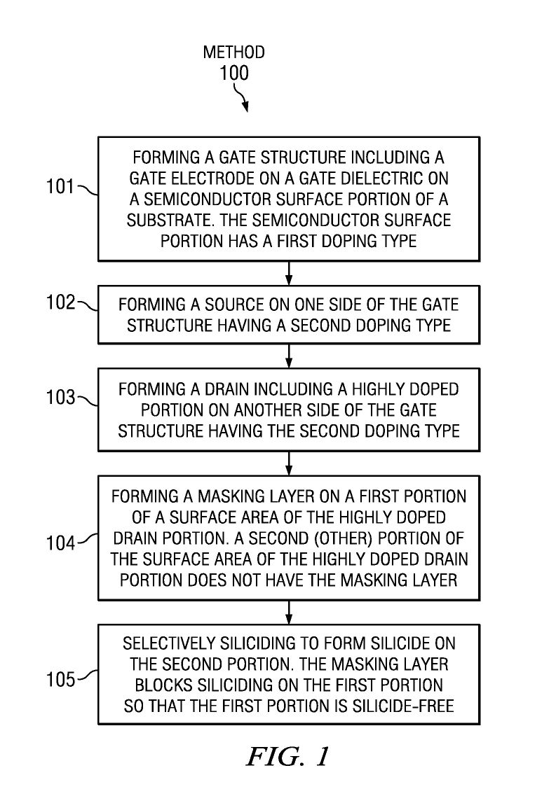

FIG. 1 is a flow chart that shows steps in an example method 100 for forming a drain extended MOS transistor having a partially silicided highly doped drain, according to an example embodiment. Method 100 is applicable to both n-channel and p-channel drain extended MOS transistors.

Step 101 comprises forming a gate structure including a gate electrode on a gate dielectric on a semiconductor surface portion of a substrate. The semiconductor surface portion has a first doping type. The gate electrode and the gate dielectric can comprise a variety of different materials. For example, the gate dielectric can comprise silicon dioxide, or a high-k dielectric material (i.e. a dielectric constant k>as compared to the 3.9 k-value of silicon dioxide), and the gate electrode can comprise polysilicon or a metal gate. Example high-k dielectrics include silicon oxynitride, hafnium silicate, zirconium silicate, hafnium dioxide and zirconium dioxide.

Step 102 comprises forming a source on one side of the gate structure having a second doping type. In step 103 a drain including a highly doped drain portion is formed on another side of the gate structure having the second doping type. Ion implantation is generally used to introduce the dopants into the source and the drain.

Step 104 comprises forming a masking layer on a first portion of a surface area of the highly doped drain portion. A second (other) portion of the surface area of the highly doped drain portion does not have the masking layer. A masking layer is used to prevent silicide from forming on the regions not to be silicided, which prevents silicide from forming to provide what is termed herein “silicide blocking”. In embodiments where the masking layer is positioned so that the selective silicide blocking happens exclusively within the highly doped (N+ or P+) area of the drain, the impact on resistance is very small and thus the Rdson of the drain extended transistor is kept low. This masking layer may be formed from a layer stack comprising one or more of, a silicon oxide layer, for example, obtained by CVD (chemical vapor deposition) from tetraethyl orthosilicate (TEOS), or a silicon nitride layer, for example, a layer of silicon nitride (Si₃N₄), or a layer silicon oxynitride. Silicide does not form on the surface regions of the wafer protected by the masking layer. A typical thickness range for the masking layer is 5 nm to 20 nm, although the masking layer thickness can be <5 nm provided silicide blocking is still provided, or be thicker than 20 nm.

Step 105 comprises selectively siliciding to form silicide on the second portion of the surface area of the highly doped drain portion. The masking layer blocks siliciding on the first portion so that the first portion remains silicide-free. Example silicide materials include titanium silicide (TiSi₂), tungsten silicide (WSi₂), cobalt silicide (CoSi₂) and nickel silicide (NiSi₂). The method can also comprise subsequently forming contacts to the respective terminals of the drain extended MOS transistor. Having drain contacts placed in highly doped drain portion having silicide thereon minimizes contact resistance, as compared to contacts to disclosed silicide-free highly doped drain portions.

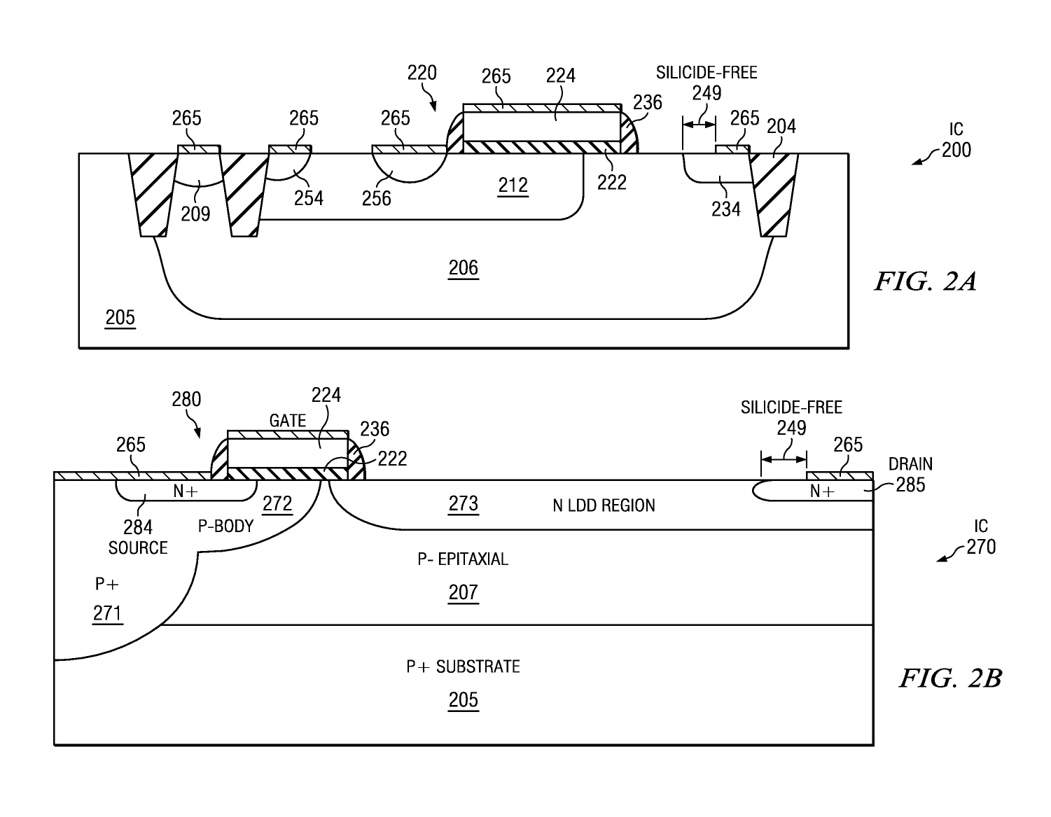

FIG. 2A is a cross-sectional depiction of an example IC 200 including at least one DENMOS transistor 220 having a partially silicided highly doped drain portion, according to an example embodiment. Although not shown, other circuitry on the IC 200 is positioned lateral to DENMOS transistor 220 on the die, such as conventional transistors, resistors, diodes and capacitors. Optional dielectric isolation regions shown as shallow trench isolation (STI) regions 204 in FIG. 2A (or other dielectric isolation technique, such as local oxidation (LOCOS)) can be formed using well known methods. Although not shown in FIG. 2A, the isolation can also be junction isolation (see FIG. 2B described below which shows junction isolation). An n-well 206 and a p-well 212 is shown within the n-well 206, typically both formed by ion implantation. Alternatively, although not shown, a p-well can be formed followed by an n-well within a p-well, where an N+ drain is then formed in the n-well.

The n-well implant is typically a series of chained implants of phosphorus, arsenic and/or antimony to counter dope the p-type substrate 205 and form a lightly doped n-well 206. P-well 212 includes a P+ p-well contact 254 and N+ source 256. IC 200 also includes an N+ n-well contact 209 to n-well 206. An N+ drain 234 is formed in the n-well 206 opposite to N+ source 256 and remotely positioned to provide a body/drift region.

DENMOS transistor 220 includes a gate structure including a gate dielectric 222 and a gate stack 224 on the gate dielectric 222, which can be formed using well known processes. The gate structure overlies the junction between the p-well 212 and the n-well 206. The portion of the p-well 212 that the gate structure overlies forms the body (or drift) region of the DENMOS transistor 220. The gate dielectric 222 may be an oxide, oxynitride, or a high-k material. The gate stack 224 may be doped or undoped polysilicon, or an electrically conductive material such as a silicide or a metal. Sidewall spacers 236 are shown on the sidewalls of the gate stack 224.

A silicide layer 265 is shown on top of the gate stack 224, the N+ source 256, N+ n-well contact 209, and P+ p-well contact 254, as well as only on a portion of the N+ drain 234. Although the silicide-free region 249 is shown on about 50% of the surface area of the N+ drain 234, in other embodiments the silicide-free portion 249 can comprise 10% to 90% of the surface area of the N+ drain 234.

The surface portion of the n-well 206 between the N+ drain 234 and gate structure which constitutes the body/drift region for DENMOS transistor 220 is also shown silicide-free. In another embodiment, STI 204 (or other dielectric isolation) is also positioned in the body region. In operation of DENMOS transistor 220, when a high voltage is applied to the N+ drain 234, the lightly doped n-well 206 fully depletes forming a drift region between the N+ drain 234 and the p-well 212. The voltage drop across this drift region may be sufficient to also protect the gate dielectric 222 under the gate stack 224 of the DENMOS transistor 220.

FIG. 2B is a cross sectional depiction of an example IC 270 including at least one LDNMOS transistor 280 having a partially silicided N+ drain, according to an example embodiment. IC 270 utilizes junction isolation. A p-epitaxial layer 207 is shown on a P+substrate 205. A P+ region 271, p-body region 272, and an n-type lightly doped drain (NLDD) region 273 are all shown. An N+ source 284 is shown on one side of the gate stack 224, and an N+ drain 285 is shown on the other side of the structure 224/222 separated by NLDD region 273. As with the DENMOS transistor shown in FIG. 2A, although the silicide-free region 249 of LDNMOS transistor 280 is shown comprising about 50% of the surface area of the N+ drain 285, in other embodiments the silicide-free portion 249 can comprise 10% to 90% of the surface area of the N+ drain 285.

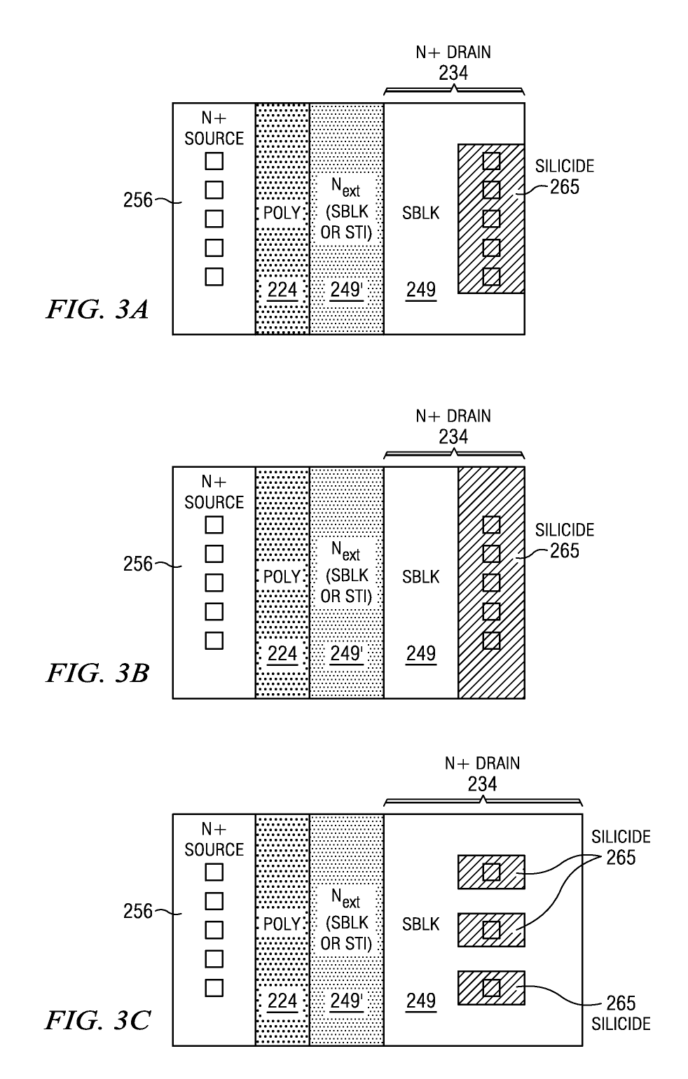

FIGS. 3A-D shows top views of several example DENMOS transistors having silicide-free N+ drain configurations including C-shaped, rectangular, ring interdigitated, and circular/racetrack shaped, respectively, according to example embodiments. “SBLK” stands for silicide block, which are silicide-free N+ drain regions. The region shown in a dashed rectangle as Next 249′ corresponds to the body/drift region between the gate stack 224 shown as polysilicon (poly) and the N+ drain 234 which can optionally include STI (or other dielectric isolation) as described above. Square boxes on the N+ source 256 and N+ drain 234 in FIGS. 3A-3D indicate contacts, in which subsequently formed metal makes contact thereto, typically a multi-layer metal interconnect structure as known in the art. Drain contacts are shown placed in areas of the N+ drain 234 having a silicide layer 265 thereon to minimize the contact resistance and series resistance.

Although silicide layer 265 is not shown on the source 256 and gate stack 224 in FIG. 3A (and FIGS. 3B-3D described below), in some embodiments the source 256 and gate stack 224 include silicide layer 265 thereon, particularly for embodiments where the gate stack 224 comprises polysilicon. In some embodiments disclosed silicide blocking can be used on a portion of the source 256 so that only the contact area of the source is silicided.

Simulation results have shown more uniform current conduction (current spreading) with selective silicide blocking over a portion of the N+ drain region and resulting lower self-heating. Moreover, as described below, experiments performed have verified the ESD performance of disclosed DEMOS/LDMOS transistors can be restored to intrinsic CMOS levels (levels obtained without silicide on the N+ drain) by selective silicide blocking over a portion of the N+ drain region. Although generally described relative to n-channel DEMOS/LDMOS transistors, as noted above, disclosed embodiments also apply to p-channel DEMOS/LDMOS transistors.

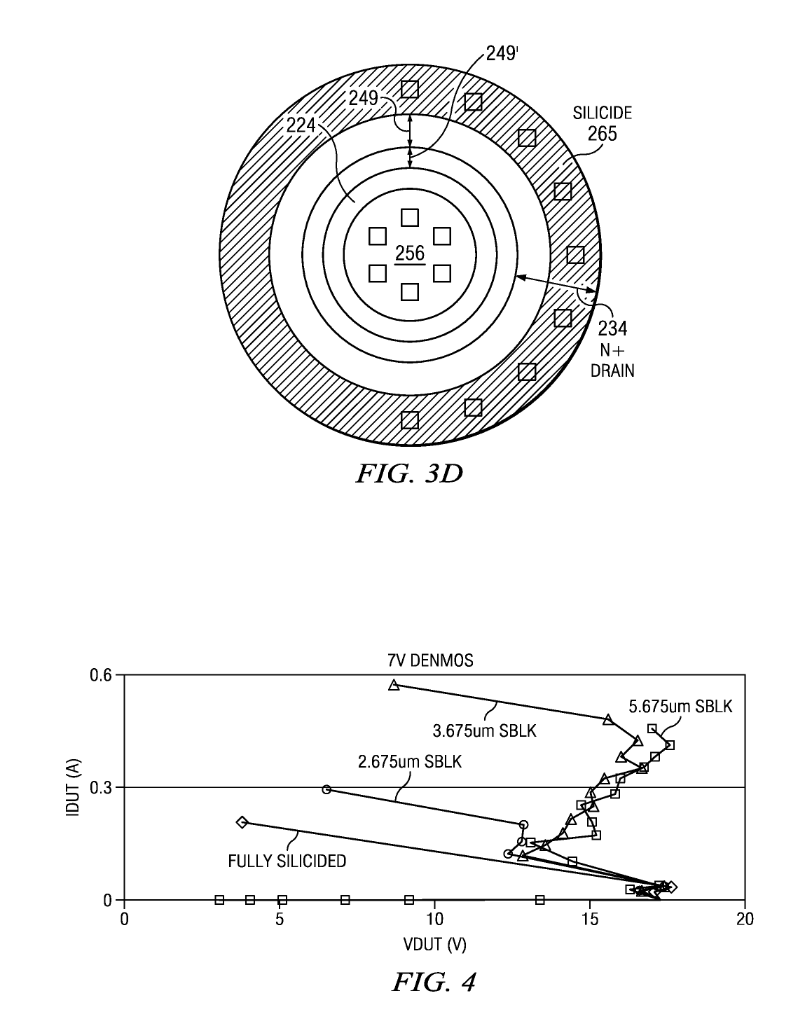

FIG. 4 shows the ESD performance improvement for disclosed 7V DENMOS transistors for N+ drains having various silicide blocking lengths vs. a control 7V DENMOS transistor (i.e. the transistor tolerates drain-to-source voltages up to 7 volts at its input/output terminals) having a fully silicided N+ drain, according to an example embodiment. The curve shown as “fully silicided” represents the control DENMOS device, which has no silicide blocking on the N+ drain (zero silicide blocking length), and thus has silicide over the full area of the N+ drain. The measurements performed provide evidence that for a disclosed 7V DENMOS the ESD improvement is proportional to SBLK length up to 3.6 μm which then saturates at around 5.6 μm. The best SBLK length value was found to vary depending on the DENMOS rating (e.g., the SBLK length for 20V DENMOS is around 5 μm). The maximum current capability under ESD conditions (I_{DUT}) is in the range of 3-7 mA/μm (I_{DUT} is normalized to the gate width).

Disclosed embodiments can be applied to discrete drain extended n-channel and p-channel MOS transistors, and ICs including such transistors. Based on the ESD robustness obtained, disclosed drain extended MOS transistors can provide self ESD protection. Disclosed drain extended MOS transistors can also be used, for example, as dedicated clamps for power supply protection, or as high voltage transistors in ICs.

Disclosed embodiments can be integrated into a variety of process flows to form a variety of different discrete and IC devices and related products. Such devices may include various elements therein and/or layers thereon, including barrier layers, dielectric layers, device structures, active elements and passive elements including source regions, drain regions, bit lines, bases, emitters, collectors, conductive lines, conductive vias, etc. Moreover, disclosed embodiments can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. A method of forming a drain extended metal-oxide-semiconductor (MOS) transistor, comprising:
forming a gate structure including a gate electrode on a gate dielectric on a semiconductor surface portion of a substrate, said semiconductor surface portion having a first doping type;
forming a source on one side of said gate structure comprising a second doping type;
forming a drain including a highly doped drain portion on another side of said gate structure comprising said second doping type;
forming a masking layer on a first portion of a surface area of said highly doped drain portion, wherein a second portion of said surface area of said highly doped drain portion does not have said masking layer, wherein the masking layer is also formed on at least a part of the source, and
selectively siliciding to form silicide on said second portion, wherein said masking layer blocks siliciding on said first portion and the at least part of the source so that said first portion and the at least part of the source is silicide-free.

2. The method of claim 1, wherein said second doping type comprises n-type and said drain extended MOS transistor comprises a drain extended n-channel MOS (DENMOS) transistor having a n-type drift region in said semiconductor surface portion between said gate structure and said highly doped drain portion.

3. The method of claim 1, wherein said wherein said second doping type comprises n-type and said drain extended MOS transistor comprises an n-channel lateral diffused MOS (LDNMOS) transistor having a n-type lightly doped drain (NLDD) region in said semiconductor surface portion between said gate structure and said highly doped drain portion.

4. The method of claim 1, wherein said silicide-free portion comprises 10% to 90% of said surface area of said highly doped drain portion.

5. The method of claim 1, wherein said masking layer comprises a silicon oxide layer, silicon nitride layer, or a silicon oxynitride layer.

6. The method of claim 1, wherein said semiconductor surface portion comprises at least one well.

7. The method of claim 1, further comprising forming contacts to said highly doped drain portion exclusively to said second portion.

8. A drain extended MOS transistor, comprising:
a substrate having a semiconductor surface portion comprising a first doping type;
a gate structure including a gate electrode on a gate dielectric on said semiconductor surface portion;
a source on one side of said gate structure comprising a second doping type, and
a drain on another side of said gate structure having said second doping type including a highly doped drain portion having surface area that is partially silicided,
wherein said partially silicided highly doped drain portion comprises a silicide layer on a second portion of said surface area, and wherein a first portion of said surface area and at least part of a surface of the source are silicide-free.

9. The drain extended MOS transistor of claim 8, wherein said drain extended MOS transistor comprises a drain extended n-channel MOS (DENMOS) transistor having an n-type drift region in said semiconductor surface portion between said gate structure and said highly doped drain portion.

10. The drain extended MOS transistor of claim 8, wherein said drain extended MOS transistor comprises a lateral diffused n-channel MOS (LDNMOS) transistor having an n-type lightly doped drain (NLDD) region in said semiconductor surface portion between said gate structure and said highly doped drain portion.

11. The drain extended MOS transistor of claim 8, wherein said silicide-free portion comprises 10% to 90% of said surface area.

12. The drain extended MOS transistor of claim 8, wherein said semiconductor surface portion comprises at least one well.

13. The drain extended MOS transistor of claim 8, further comprising a dielectric isolation region between said gate structure and said highly doped drain portion.

14. The drain extended MOS transistor of claim 8, further comprising contacts to said highly doped drain portion, said contacts being exclusively to said second portion.

15. A drain extended MOS transistor, comprising:
a substrate having a semiconductor surface portion comprising a first doping type;
a gate structure including a gate electrode on a gate dielectric on said semiconductor surface portion;
a source on one side of said gate structure comprising a second doping type, wherein said source is silicide-free, and
a drain on another side of said gate structure having said second doping type including a highly doped drain portion having surface area that is partially silicided,
wherein said partially silicided highly doped drain portion comprises a silicide layer on a second portion of said surface area, and wherein a first portion of said surface area is silicide-free.
